(19) United States
(12) Patent Application Publication
(10) Pub. No.: US 2019/0006538 A1
(43) Pub. Date: Jan. 3, 2019

(54) SOLAR CELL HAVING ELECTROCHROMIC PORTION INSERTED THEREINTO AND METHOD OF FABRICATING THE SAME

(71) Applicant: KOREA INSTITUTE OF ENERGY RESEARCH, Daejeon (KR)

(72) Inventors: Ara CHO, Daejeon (KR); Junsik CHO, Daejeon (KR); Jaeho YUN, Daejeon (KR); Sejin AHN, Daejeon (KR); Jihye GWAK, Daejeon (KR); Jinsu YOO, Daejeon (KR); Seungkyu AHN, Daejeon (KR); Joohyung PARK, Daejeon (KR); Youngjoo EO, Daejeon (KR); Kihwan KIM, Daejeon (KR)

(21) Appl. No.: 16/013,939

(22) Filed: Jun. 21, 2018

(30) Foreign Application Priority Data
Jun. 30, 2017 (KR) 10-2017-0083369

(51) Int. Cl. H01L 31/0224; G02F 1/163; G02F 1/153; G02F 1/157; H01L 31/055

(52) U.S. Cl. CPC H01L 31/022425; G02F 1/163; H01L 31/055; G02F 1/157; G02F 1/1533

(57) ABSTRACT

The present invention relates to a solar cell having an electrochromic portion inserted thereinto and a method of fabricating the same. The solar cell includes a light-transmitting portion formed on a substrate and an electrochromic portion formed at the light-transmitting portion and having an electrochromic property, so that beauty may be improved through the color implementation, light transmittance may also be adjusted according to an external environment, and thus it is possible to flexibly cope with a change in external environment.

### CROSS-REFERENCE TO RELATED APPLICATION

This application claims priority to and the benefit of Korean Patent Application No. 2017-0083369, filed on Jun. 30, 2017, the disclosure of which is incorporated herein by reference in its entirety.

This work was supported by the Korea Institute of Energy Technology Evaluation and Planning (KETEP) and the Ministry of Trade, Industry & Energy (MOTIE) of the Republic of Korea (No. 20163010012560).

### BACKGROUND

### 1. Field of the Invention

The present invention relates to a solar cell having an electrochromic portion inserted thereinto and a method of fabricating the same, and more particularly, to a solar cell having an electrochromic portion inserted thereinto, which is capable of implementing a variety of colors due to the electrochromic portion having an electrochromic property inserted thereinto, and a method of fabricating the same.

### 2. Discussion of Related Art

Recently, as the exhaustion of existing energy sources such as petroleum and coal is expected, interest in alternative energy to replace them is increasing. Among alternative energy sources, solar cells have entered the spotlight as a next-generation battery which directly converts solar energy into electrical energy using a semiconductor device.

Meanwhile, the government considers that it is important to prepare measures for a high-performance building envelope as one of energy-saving measures. Also, as the power generating efficiency of solar cells, which have entered the spotlight as a next-generation battery, is improved, attention has been paid to the building-integrated photovoltaic (BIPV) system using solar cells as building envelope finishes or windows.

The BIPV system requires power supply through its own electric power generation while satisfying the performance as building envelope finishes. Therefore, studies have been conducted for improving the light transmittance and incidence efficiency of solar cells, and the appearance and display function of solar cells is becoming important.

However, conventional solar cells exhibit a blue-black or red-brown color. Therefore, when solar cells are installed so as to be exposed to the outside of a building or an automobile, a variety of colors of solar cells are required in terms of aesthetics in accordance with consumer preference.

For this purpose, solar cells may include a thin film layer colored with a specific coloring material to implement a predetermined color. However, when the coloring material is used, transparency is degraded due to inherent properties of the coloring material, and thus the amount of light incident upon a solar cell is reduced. Therefore, the selection range of the color was inevitably limited.

### SUMMARY OF THE INVENTION

The present invention is designed to solve the aforementioned problems and it is an object of the present invention to provide a solar cell having an electrochromic portion inserted thereinto, in which an electrochromic portion having an electrochromic property is formed at a light-transmitting portion on a substrate so that beauty can be improved through the color implementation, and a method of fabricating the same.

It is another object of the present invention to provide a solar cell having an electrochromic portion inserted thereinto, in which transparency is controlled by adjusting the height of an electrochromic portion such that the area of a light-absorbing layer is changed, and thus the amount of incident light may be increased to implement a variety of colors, thereby an interior effect may be obtained, light having a certain wavelength may be effectively blocked according to a change in color, and the inside may also be blocked from being seen from the outside, and a method of fabricating the same.

The present invention is designed to achieve the above objects and provides a solar cell having an electrochromic portion inserted thereinto, which includes a back electrode layer disposed on a substrate; a light-absorbing layer disposed on the back electrode layer; a front electrode layer and a buffer layer disposed on the light-absorbing layer; a light-transmitting portion including a light-transmitting region dividing the back electrode layer into multiple portions; an electrochromic portion provided in the light-transmitting portion and including a color adjustment region formed so as to implement a variety of colors according to applied voltage; a first pattern portion disposed at one side of the electrochromic portion and partially exposing the back electrode layer through an opening in the light-absorbing layer and the buffer layer; and a second pattern portion partially exposing the back electrode layer through an opening in the front electrode layer in the presence of a connection wiring formed of a transparent conductive material inserted into the inside of the first pattern portion during the formation of the front electrode layer in the first pattern portion.

According to the present invention, the electrochromic portion may change a color by changing transparency according to voltage applied to the portion between the back electrode layers.

According to the present invention, the electrochromic portion may be formed to have the same height as that of the light-absorbing layer.

According to the present invention, the electrochromic portion may be formed higher than an upper surface of the back electrode layer and lower than an upper surface of the light-absorbing layer.

According to the present invention, the electrochromic portion may have a structure capable of changing a color through an electrochemical oxidation-reduction reaction, and include an electrochromic component and an electrolyte layer.

According to the present invention, the electrochromic portion may be formed to partially overlap the back electrode layer.

According to the present invention, a barrier for blocking an electric current flow may be formed from an upper surface of the back electrode layer to an upper surface of the buffer layer in a way that it contacts the electrochromic portion from the side.

In addition, the present invention provides a method of fabricating a solar cell having an electrochromic portion inserted thereinto, which includes forming back electrode layers on a substrate so as to be spaced apart from each other at an interval; disposing a mask on the back electrode layer and depositing a light-transmitting portion in a light-transmitting region on a substrate on which the mask is not formed; inserting, into the light-transmitting portion, an electrochromic portion including a color adjustment region formed so as to implement a variety of colors according to applied voltage; forming a buffer layer and a light-absorbing layer, on the back electrode layer and the electrochromic portion; forming a first pattern portion at one side of the electrochromic portion so as to partially expose the back electrode layer; forming a front electrode layer on the buffer layer and in the first pattern portion and forming a connection wiring by inserting a transparent conductive material into the inside of the first pattern portion during the formation of the front electrode layer in the first pattern portion; and forming, in the first pattern portion, a second pattern portion partially exposing the back electrode layer through an opening in the front electrode layer.

According to the present invention, the electrochromic portion may change a color by changing transparency according to voltage applied to the portion between the back electrode layers.

According to the present invention, the electrochromic portion may be formed to have the same height as that of the light-absorbing layer.

According to the present invention, the electrochromic portion may be formed higher than an upper surface of the back electrode layer and lower than an upper surface of the light-absorbing layer.

According to the present invention, the electrochromic portion may have a structure capable of changing a color through an electrochemical oxidation-reduction reaction and include an electrochromic component and an electrolyte layer.

According to the present invention, the electrochromic portion may be formed to partially overlap the back electrode layer.

According to the present invention, a barrier for blocking an electric current flow may be formed from an upper surface of the back electrode layer to an upper surface of the buffer layer in a way that it contacts the electrochromic portion from the side.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a cross-sectional view of a solar cell having an electrochromic portion inserted thereinto according to a first embodiment of the present invention;

FIG. 2 is a cross-sectional view of a solar cell having an electrochromic portion inserted thereinto according to a second embodiment of the present invention;

FIG. 3 is a cross-sectional view of a solar cell having an electrochromic portion inserted thereinto according to a third embodiment of the present invention; and

FIGS. 4 to 9 are cross-sectional views illustrating a method of fabricating a solar cell having an electrochromic portion inserted thereinto according to a first embodiment of the present invention.

### DETAILED DESCRIPTION OF EXEMPLARY EMBODIMENTS

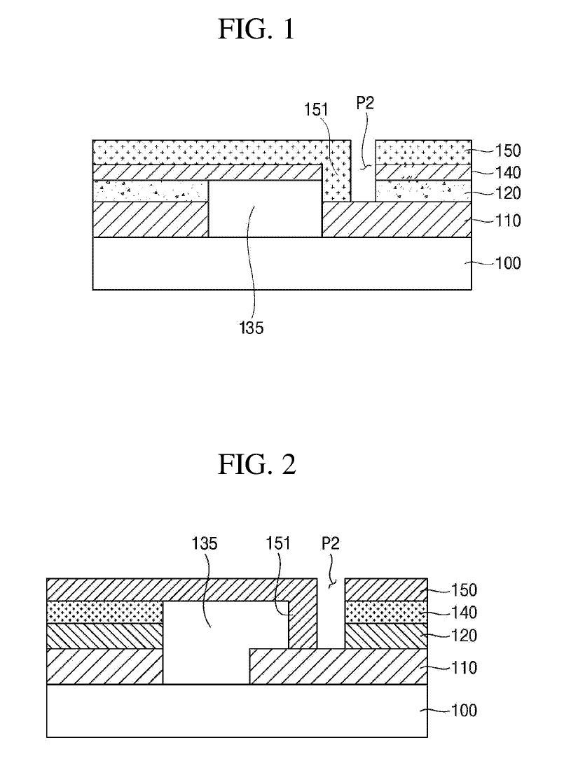

Hereinafter, embodiments of the present invention will be described in detail with reference to FIGS. 1 to 9 as follows.

FIG. 1 is a cross-sectional view of a solar cell having an electrochromic portion inserted thereinto according to an embodiment of the present invention. As shown in FIG. 1, the solar cell includes a substrate 100, a back electrode layer 110 disposed on the substrate 100, a light-absorbing layer 120 disposed on the back electrode layer 110, a front electrode layer 150 and a buffer layer 140 disposed on the light-absorbing layer 120, and a light-transmitting portion 130 including a light-transmitting region dividing the back electrode layer 110 into multiple portions.

In particular, an electrochromic portion 135 capable of implementing a variety of colors according to applied voltage may be formed at the light-transmitting portion 130.

The substrate 100 may be a glass having high light transmittance, and a ceramic substrate, a metallic substrate, a polymeric substrate, or the like may also be used. For example, a glass substrate may be soda-lime glass or high strain point soda glass.

As a metallic substrate, a substrate 100 including stainless steel or titanium may be used. As a polymeric substrate, a polyimide may be used, but the present invention is not limited thereto, and various materials having similar physicochemical properties may be used.

In addition, the substrate 100 may be a hard or soft material.

The back electrode layer 110 may be formed of a metallic material having high conductivity and excellent light reflectance, such as molybdenum, aluminum, copper, or the like, with a thickness of about 1 μm, so as to collect electric charges formed by the photoelectric effect and reflect light transmitted through the light-absorbing layer 120 to induce reabsorption into the light-absorbing layer 120.

In particular, the back electrode layer 110 may include molybdenum in consideration of high conductivity, the ohmic contact with the light-absorbing layer 120, high-temperature stability under a selenium (Se) atmosphere, and the like. That is, the back electrode layer 110 is formed through a sputter deposition process using a molybdenum target.

Molybdenum used in the back electrode layer 110 needs to have low specific resistance as an electrode and exhibit high adhesiveness to the substrate 100 so as not to cause a peeling phenomenon caused by a difference in thermal expansion coefficients.

Meanwhile, the back electrode layer 110 may be formed of molybdenum doped with alkali ions such as Na and the like. For example, when a copper-indium-gallium-selenium (CIGS)-based light-absorbing layer 120 is grown, alkali ions doped in the back electrode layer 110 may be incorporated into the light-absorbing layer 120 to advantageously affect the structure of the light-absorbing layer 120 and improve the conductivity of the light-absorbing layer 120, and thus the open-circuit voltage of the solar cell may be improved.

The back electrode layer 110 forms, on the substrate 100, groove type light-transmitting regions that are perpendicular to a lengthwise direction of the substrate 100 and lying parallel to one another, but the present invention is not limited thereto.

Alternatively, a back electrode layer pattern including groove type light-transmitting regions dividing the back electrode layer 110 into multiple portions may also be formed by depositing the back electrode layer 110 on the substrate 100 and then subjecting the back electrode layer 110 to a patterning process.

The patterning process is carried out through a mechanical scribing process or a laser scribing process. In the scribing process, a part of a back electrode layer 110 is cut off or evaporated to form a light-transmitting portion 130, and the back electrode layer 110 is divided, by the light-transmitting portion 130, into multiple portions so as to be spaced apart from each other at an interval.

As shown in FIG. 1, the light-absorbing layer 120 is formed on the back electrode layer 110.

The light-absorbing layer 120 serves to absorb external sunlight and convert solar energy into electrical energy, and generates photovoltaic power by the photoelectric effect.

The light-absorbing layer 120 is formed of a copper-indium-gallium-selenium (CIGS)-based compound including copper, indium, gallium, and selenium with a thickness of about 1 to 2 μm to form a P-type semiconductor layer. For example, a CIG-based metallic precursor film is formed on the back electrode layer 110 using a copper target, an indium target, and a gallium target to form the light-absorbing layer 120.

Afterward, the metallic precursor film reacts with selenium (Se) through a selenization process to form a CIGS-based light-absorbing layer 120.

The front electrode layer 150 may be formed of zinc-based oxide including impurities such as aluminum (Al), alumina (Al₂O₃), magnesium (Mg), gallium (Ga), and the like or a transparent conductive material such as indium tin oxide (ITO) or indium zinc oxide (IZO) to collect electric charges formed by the photoelectric effect.

In addition, the front electrode layer 150 is a window layer which forms a P-N junction with the light-absorbing layer 120, and functions as a transparent electrode in the front surface of the solar cell. Therefore, the front electrode layer 150 may be formed of zinc oxide having high light transmittance and high electroconductivity to form an electrode having low resistance.

The upper surface of the front electrode layer 150 may be subjected to texturing to reduce reflection of incident sunlight and increase absorption of light into the light-absorbing layer 120. As a result of the texturing, a ribbed pattern is formed on the upper surface of the front electrode layer 150 to reduce reflectance of incident light, and thus a large amount of light may be captured. Therefore, optical loss may be reduced.

Referring to the drawings, the light-transmitting region dividing the back electrode layer 110 is formed, and the light-transmitting portion 130 is formed in the light-transmitting region.

The light-transmitting portion 130 is filled with a transparent insulating material.

The transparent insulating material may be a strong alkali-resistant, light-resistant, and insulating material having a light transmittance of 90 to 100%. For example, the transparent insulating material may be formed of any one of polymethyl methacrylate (PMMA), which is a transparent non-crystalline resin, styrene-acrylonitrile copolymer (SAN), polycarbonate (PC), transparent acrylonitrile butadiene styrene (ABS), polyethylene terephthalate (PET), ultra high molecular weight (U-HMW) polyethylene, methyl cellulose (MC), polyoxymethylene (POM), polytetrafluoroethylene (PTFE), polypropylene oxide (PPO), and polyurethane (PUR).

The light-transmitting portion 130 may be formed selectively in the light-transmitting region through a thermal adsorption, injection, or filling method.

For example, the light-transmitting portion 130 may be formed through any one method among dispensing, screen printing, hot pressing, and photolithography processes. In an exemplary embodiment of the present invention, the light-transmitting portion 130 is formed through a screen printing process.

The screen printing process is a process for forming a predetermined layer by transferring the light-transmitting portion 130 onto the substrate 100 using a screen and a squeegee.

In addition, an electrochromic portion 135 capable of implementing a variety of colors is formed at the light-transmitting portion 130.

The transparency of the light-transmitting portion 130 is changed according to voltage applied to the portion between the back electrode layers to induce the color change of the electrochromic portion 135. The electrochromic portion 135 includes an electrochromic component. When voltage is applied, the transparency of the light-transmitting portion 130 is decreased, and when voltage is not applied, the transparency thereof is increased. That is, on a day with lots of sunlight, a relatively large amount of electricity is produced, and thus the electrochromic component becomes more darkly discolored.

The electrochromic portion 135 has a structure capable of changing a color through an electrochemical oxidation-reduction reaction and includes an electrochromic component and an electrolyte layer.

The electrochromic component has an electrochromic property, which refers to having light absorbance that changes as an electrochemical oxidation-reduction reaction progresses. The electrochemical oxidation-reduction reaction in the electrochromic component occurs, reversibly, depending on whether the voltage is applied or not and the intensity of the voltage, and thus the transparency and light absorbance of the electrochromic component may be reversibly changed. Such an electrochromic component may be formed of any one electrochromic material among WO₃, MoO₃, TiO₃, Nb₂O₅, V₂O₅, IrO₂, Rh₂O₂, and NiO.

The electrolyte layer may be an ionic conductor which allows the movement of electric charges. Preferably, the electrolyte layer may include a metal salt such as LiClO₄ or the like and a polymer material such as polyethylene oxide (PEO) or the like. Such an electrolyte layer may be formed of a material which allows the movement of electric charges, in addition to LiClO₄ and PEO.

The electrochromic portion 135 serves to adjust light transmittance by becoming dark or transparent according to whether the voltage is applied or not.

In addition, the electrochromic portion 135 is capable of implementing a variety of colors by changing the color to be developed, and thus an interior effect may be obtained.

Additionally, the electrochromic component may block light having a certain wavelength by developing a specific color, and thus damage caused by light having a harmful wavelength such as ultraviolet rays may be reduced.

The solar cell according to the present invention may further include a controller configured to determine whether to manually or automatically control the development or coloration.

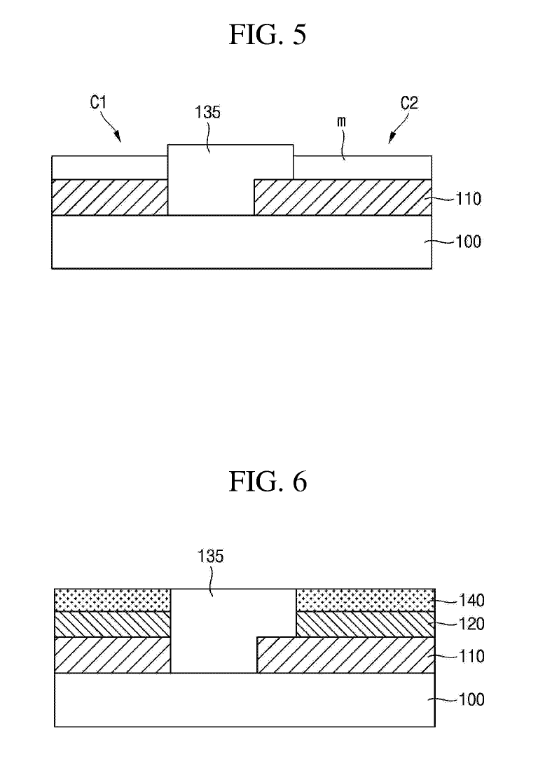

As shown in FIG. 5, the electrochromic portion 135 may function as a boundary for separating a plurality of unit cells, such as a first cell C1 and a second cell C2, from one another on the substrate 100.

The electrochromic portion 135 and each of the unit cells C1 and C2 may be alternately disposed. That is, the electrochromic portion 135 is provided between the first cell C1 and the second cell C2. Therefore, beauty may be improved through the color implementation for the solar cell, and light transmittance may also be adjusted according to an external environment, making it possible to flexibly cope with a change in external environment.

As shown in the drawings, the electrochromic portion 135 may be formed to have the same height as that of the light-absorbing layer 120 or may be formed higher than an upper surface of the back electrode layer 110 and lower than an upper surface of the light-absorbing layer 120.

Accordingly, the thickness of the light-absorbing layer 120 on the electrochromic portion 135 varies. When the thickness of the light-absorbing layer 120, which is an opaque material, is decreased, the light-absorbing layer 120 becomes relatively transparent, and when the thickness thereof is increased, the light-absorbing layer 120 becomes relatively opaque. Therefore, the transparency of the light-absorbing layer 120 varies according to the thickness thereof.

In addition, as shown in the drawings, the electrochromic portion 135 is formed to partially overlap the back electrode layer 110.

The electrochromic portion 135 partially overlaps the back electrode layer 110 as described above, so that the area of the electrochromic portion 135 may be relatively large. Therefore, the transparency of the solar cell may be adjusted according to the area of the electrochromic portion 135.

A mask (m) with a predetermined pattern is disposed on the back electrode layer 110, and the electrochromic portion 135 is formed at a part on a substrate 100 on which the mask (m) is not provided. In this case, the electrochromic portion 135 is formed such that an upper surface thereof is located higher than that of the mask (m).

Meanwhile, the buffer layer 140 is formed between the light-absorbing layer 120 and the front electrode layer 150.

The buffer layer 140 is formed on the light-absorbing layer 120, and there may be at least one buffer layer 140 provided on the light-absorbing layer 120. The buffer layer 140 may be formed by depositing cadmium sulfide (CdS). In this case, the buffer layer 140 is an N-type semiconductor layer, and the light-absorbing layer 120 is a P-type semiconductor layer. Therefore, the light-absorbing layer 120 and the buffer layer 140 form a P-N junction.

In the buffer layer 140, a zinc oxide layer may be further formed on the cadmium sulfide through a sputtering process using a zinc oxide (ZnO) target.

Such a buffer layer 140 has a refractive index of about 2.2 to 2.6.

The buffer layer 140 is a layer which reduces the band gap difference between a P-type light-absorbing layer 120 and an N-type front electrode layer 150 and reduces the recombination of electrons and holes, which may occur at the interface between the light-absorbing layer 120 and the front electrode layer 150, and may be formed through chemical bath deposition (CBD), atomic layer deposition (ALD), ion layer gas reaction (ILGAR), or the like.

After the light-absorbing layer 120 and the buffer layer 140 are formed as described above, a first patterning process is carried out. That is, a first pattern portion P1 cutting through the light-absorbing layer 120 and the buffer layer 140 is formed.

In the first patterning process, a first pattern portion P1 may be formed through mechanical scribing in a direction parallel to the electrochromic portion 135, at a position spaced apart from the electrochromic portion 135, but the present invention is not limited thereto, and a first pattern portion P1 may also be formed through a laser scribing process.

The first pattern portion P1 formed through the first patterning process allows the back electrode layer 110 disposed at one side of the electrochromic portion 135 and corresponding to a second cell C2 to be partially exposed.

The light-absorbing layer 120 and the buffer layer 140 of unit cells C1 and C2 may be separated for each unit cell by the first pattern portion P1.

During the formation of the front electrode layer 150 on the buffer layer 140, a transparent conductive material may be inserted into the inside of the first pattern portion P1 to form a connection wiring 151.

Therefore, the back electrode layer 110 and the front electrode layer 150 may be electrically connected through the connection wiring 151.

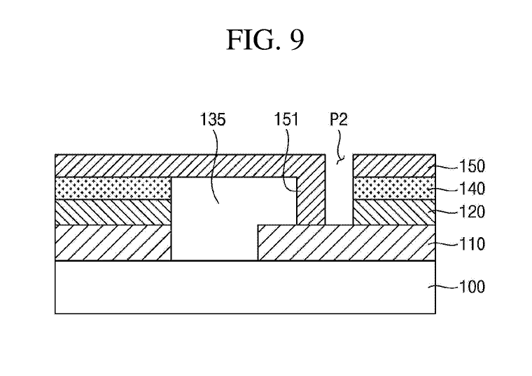

As shown in FIG. 9, after the front electrode layer 150 is formed, a second patterning process in which an opening cutting through the front electrode layer 150 and the connection wiring 151 is made is carried out. That is, a second pattern portion P2 cutting through the front electrode layer 150 and the connection wiring 151, which are formed in the inside of the first pattern portion P1, is formed.

The second patterning process may be carried out through a mechanical scribing process or a laser scribing process, and the part in the back electrode layer 110 which was previously exposed by the first patterning process may be partially exposed again.

The second pattern portion P2 cuts through the front electrode layer 150 and is extended to the upper surface of the back electrode layer 110 to form multiple photoelectric conversion cells.

The second pattern portion P2 is formed to have a width capable of separating the first cell C1 and the second cell C2 so that the first cell C1 and the second cell C2 may be divided. That is, the front electrode layer 150 may be provided on each of the first cell C1 and the second cell C2 by the second pattern portion P2.

In the second pattern portion P2, the connection wiring 151 connected with the front electrode layer 150 of the first cell C1 partially remains. This is because the second pattern portion P2 is formed in such a way that the connection wiring 151 formed at a side surface of the electrochromic portion 135 partially remains.

Therefore, the first cell C1 and the second cell C2 may be electrically connected by the connection wiring 151. That is, the connection wiring 151 electrically connects the back electrode layer 110 of the second cell C2 with the front electrode layer 150 of the first cell C1 adjacent to the second cell C2.

The solar cell according to the present invention may include a color adjustment region formed between the unit solar cells. That is, the electrochromic portion 135 is formed at the light-transmitting region between the first cell C1 and the second cell C2, and each of the cells and the light-transmitting region may be alternately provided in a longitudinal direction.

The color adjustment region may be formed to have almost the same width as that of the unit solar cell, but the present invention is not limited thereto. Also, the position, size, and area of the color adjustment region may be adjusted to control the degree of light transmittance.

The electrochromic portion 135 is formed between the unit solar cells as described above, so that the solar cell expresses a variety of colors, and a transparent electrochromic component is adsorbed onto the entire surface of the electrochromic portion 135 to control the degree of light transmittance. As a result, light transmittance and aesthetics may be improved.

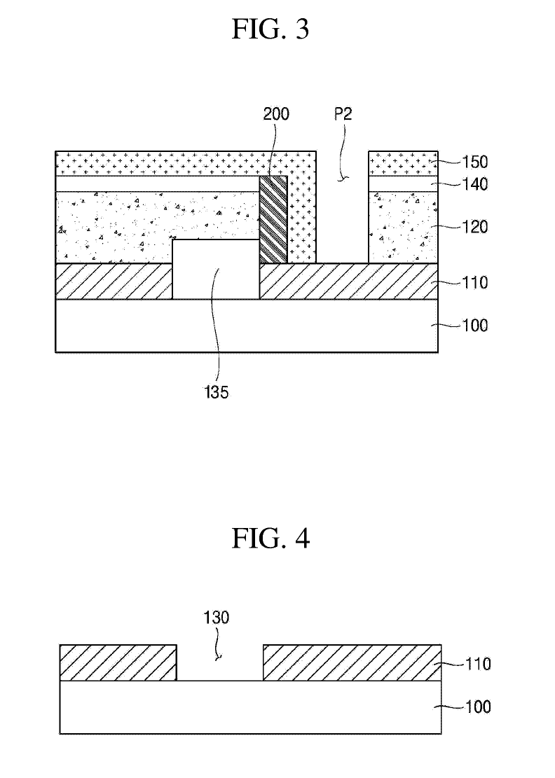

As shown in FIG. 3, the back electrode layer 110 and the front electrode layer 150 are electrically connected by the connection wiring 151, the first cell C1 and the second cell C2 are serially connected, and thus an electric current flow is generated across the first cell C1 and the second cell C2, which is referred to as a photovoltaic effect. The electric current flow generated by the photovoltaic effect allows an electric current to flow to an external load connected to the solar cell to operate the external load. That is, the back electrode layer 110 of the first cell C1 is electrically connected to the light-absorbing layer 120, the front electrode layer 150, and the back electrode layer 110 of the second cell C2. Accordingly, a serial connection structure of the unit cells C1 and C2 is formed.

Although such a solar cell allows an electric current to be stably supplied from the back electrode layer 110 to the front electrode layer 150, an electric current moving to the light-absorbing layer 120 on the light-transmitting portion 130 also flows to the front electrode layer 150 through a side surface of the light-transmitting portion 130. As a result, electric current is lost, and the light-absorbing efficiency of the light-absorbing layer 120 is degraded.

Therefore, in order to maintain the stable and smooth flow of electric current from the back electrode layer 110 to the front electrode layer 150 at the light-transmitting portion 130, a vertical barrier for blocking an electric current flow 200 is formed from an upper surface of the back electrode layer 110 to an upper surface of the buffer layer 140 in a way that it contacts the electrochromic portion 130 from the side.

The barrier for blocking an electric current flow 200 is an insulator which does not transfer an electric current due to its high resistance to an electric current, and allows an electric current flowing from the back electrode layer 110 to reach the front electrode layer 150 at an upper part through a stable flow path.

Therefore, the barrier for blocking an electric current flow 200 may block the unstable supply of an electric current between the first cell C1 and the second cell C2.

FIGS. 4 to 9 are cross-sectional views illustrating a method of fabricating a solar cell according to the present invention. The method of fabricating a solar cell according to the present invention will be described. First, a mask (not shown) is disposed on a substrate 100, and a back electrode layer 110 is formed at a part on a substrate on which the mask is not provided, so that the back electrode layer 110 is divided into multiple portions (see FIG. 4).

The back electrode layer 110 may be formed by applying a conductive paste onto the substrate 100 and then performing thermal treatment or may be formed through a plating process or the like.

In addition, the back electrode layer 110 may be formed through a sputter deposition process using a molybdenum target. In this case, the back electrode layers 110 are deposited to be spaced apart from each other at a constant interval on the substrate 100.

Alternatively, the back electrode layer 110 deposited on the substrate 100 may be subjected to a patterning process to form a light-transmitting region dividing the back electrode layer 110.

As shown in FIG. 5, a mask (m) with a predetermined pattern is disposed on the back electrode layer 110, and a light-transmitting portion 130 is formed in the light-transmitting region, which is a part on a substrate 100 on which the mask (m) is not provided. Subsequently, an electrochromic portion 135 including an electrochromic material is formed at the light-transmitting portion 130.

Accordingly, the electrochromic portion 135 is formed such that an upper surface thereof is located higher than that of the mask (m).

As shown in the drawings, the mask (m) is removed, and the electrochromic portion 135 is formed such that an upper surface thereof is located higher than that of the back electrode layer 110.

In addition, the electrochromic portion 135 may be formed to partially overlap the back electrode layer 110.

The electrochromic portion 135 partially overlaps the back electrode layer 110 as described above, so that the area of the electrochromic portion 135 may be relatively large. Therefore, the transparency of the solar cell may be adjusted according to the area of the electrochromic portion 135.

Subsequently, as shown in FIG. 6, a light-absorbing layer 120 and a buffer layer 140 are formed at an interval on the back electrode layer 110.

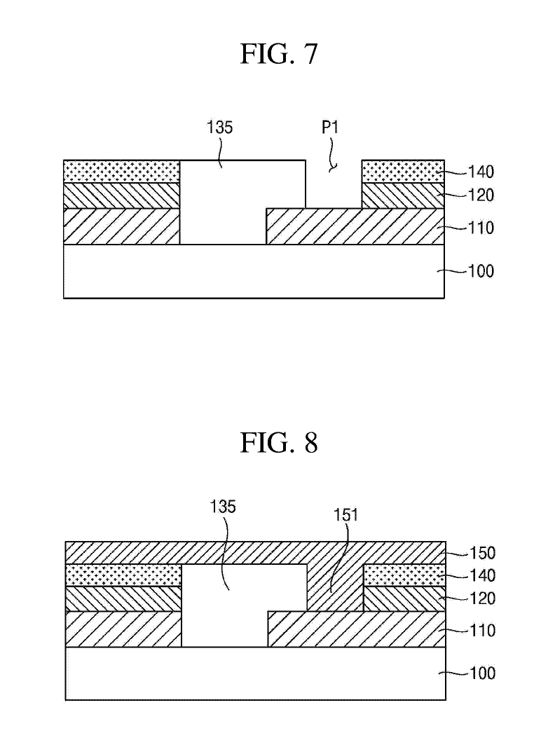

After the light-absorbing layer 120 and the buffer layer 140 are formed, a first patterning process is carried out (see FIG. 7).

In the first patterning process, a first pattern portion P1 may be formed, through a mechanical scribing or laser scribing process, in a direction parallel to the electrochromic portion 135, at a position spaced apart from the electrochromic portion 135.

The first pattern portion P1 divides the light-absorbing layer 120 into multiple portions and is extended to the upper surface of the back electrode layer 110 to selectively expose the back electrode layer 110.

Next, as shown in FIG. 8, a transparent conductive material is applied on the buffer layer 140 to form a front electrode layer 150 and a connection wiring 151.

During the formation of the front electrode layer 150 on the buffer layer 140, the transparent conductive material may be inserted into the inside of the first pattern portion P1 to form a connection wiring 151.

Therefore, the back electrode layer 110 and the front electrode layer 150 may be electrically connected by the connection wiring 151.

As shown in FIG. 9, a second pattern portion P2 cutting through the front electrode layer 150 and the connection wiring 151 formed in the inside of the first pattern portion P1 is formed.

The second pattern portion P2 may be formed through a mechanical scribing process or a laser scribing process, and the part in the back electrode layer 110 which was previously exposed by the first patterning process may be partially exposed again.

The second pattern portion P2 is formed to have a width capable of separating a first cell C1 and a second cell C2 so that the first cell C1 and the second cell C2 may be divided. That is, the front electrode layer 150 is provided on each of the first cell C1 and the second cell C2 by the second pattern portion P2.

In the second pattern portion P2, the connection wiring 151 connected with the front electrode layer 150 of the first cell C1 partially remains. This is because the second pattern portion P2 is formed in such a way that the connection wiring 151 formed at a side surface of the electrochromic portion 135 partially remains.

Therefore, the first cell C1 and the second cell C2 may be electrically connected by the connection wiring 151. That is, the connection wiring 151 electrically connects the back electrode layer 110 of the second cell C2 with the front electrode layer 150 of the first cell C1 adjacent to the second cell C2.

The process of forming the back electrode layer 110, the light-transmitting portion 130, the light-absorbing layer 120, the buffer layer 140, and the first pattern portion P1 on the substrate 100, which is a preceding process, is the same as shown in FIGS. 4 to 6, so detailed description thereof will be omitted. Also, the second patterning process, which is a succeeding process, is the same as shown in FIG. 9, so detailed description thereof will be omitted.

Therefore, according to the present invention, the electrochromic portion 135 is formed to have almost the same height as that of the light-absorbing layer 120 or slightly higher than the back electrode layer 110 and lower than the light-absorbing layer 120, so that the transparency is adjusted to improve the light-absorbing efficiency of the light-absorbing layer 120, and thus it is possible to flexibly cope with a change in external environment.

In addition, the electrochromic portion 135 is capable of expressing a variety of colors and controlling the degree of light transmittance, and thus light transmittance and aesthetics may be improved.

Accordingly, a decorating effect may be obtained, light having a certain wavelength may be effectively blocked according to a change in color, and the inside may also be blocked from being seen from the outside. Also, the effect of simultaneously transmitting and shielding sunlight may be obtained, and thus the consumption of electrical energy for lighting may be reduced.

In addition, by installing the barrier for blocking an electric current flow 200 at a side surface of the light-transmitting portion 130, the stable and smooth flow of an electric current from the back electrode layer 110 to the front electrode layer 150 may be maintained, and thus loss of electric current may be reduced.

According to a solar cell having an electrochromic portion inserted thereinto and a method of fabricating the same according to the present invention, an electrochromic portion having an electrochromic property is formed at a light-transmitting portion on a substrate so that beauty can be improved through the color implementation.

In addition, transparency is controlled by adjusting the height of an electrochromic portion such that the area of a light-absorbing layer is changed, and thus the amount of incident light can be increased to implement a variety of colors, thereby a decorating effect can be obtained, light having a certain wavelength can be effectively blocked according to a change in color, and the inside can also be blocked from being seen from the outside.

While exemplary embodiments of the present invention have been illustrated and described above, the present invention is not limited to the aforementioned exemplary embodiments. Those skilled in the art may variously modify the present invention without departing from the gist of the present invention claimed by the appended claims, and it should be construed that the modifications are within the scope of the claims.

### LIST OF REFERENCE NUMERALS

| | |
|---|---|
| 100: substrate | 110: back electrode layer |
| 120: light-absorbing layer | 135: electrochromic portion |
| 140: buffer layer | 150: front electrode layer |
| 200: barrier | P2: second pattern portion |
| P1: first pattern portion | C2: second cell |
| C1: first cell | |

What is claimed is:

1. A solar cell having an electrochromic portion inserted thereinto, the solar cell comprising:
a back electrode layer disposed on a substrate;
a light-absorbing layer disposed on the back electrode layer;
a front electrode layer and a buffer layer disposed on the light-absorbing layer;
a light-transmitting portion including a light-transmitting region dividing the back electrode layer into multiple portions;
an electrochromic portion provided in the light-transmitting portion and including a color adjustment region formed so as to implement a variety of colors according to applied voltage;
a first pattern portion disposed at one side of the electrochromic portion and partially exposing the back electrode layer through an opening in the light-absorbing layer and the buffer layer; and
a second pattern portion partially exposing the back electrode layer through an opening in the front electrode layer in the presence of a connection wiring formed of a transparent conductive material inserted into the inside of the first pattern portion during a formation of the front electrode layer in the first pattern portion.

2. The solar cell of claim 1, wherein the electrochromic portion changes a color by changing transparency according to voltage applied to the portion between the back electrode layers.

3. The solar cell of claim 1, wherein the electrochromic portion is formed to have the same height as that of the light-absorbing layer.

4. The solar cell of claim 1, wherein the electrochromic portion is formed higher than an upper surface of the back electrode layer and lower than an upper surface of the light-absorbing layer.

5. The solar cell of claim 1, wherein the electrochromic portion has a structure capable of changing a color through an electrochemical oxidation-reduction reaction and includes an electrochromic component and an electrolyte layer.

6. The solar cell of claim 1, wherein the electrochromic portion is formed to partially overlap the back electrode layer.

7. The solar cell of claim 1, wherein a barrier for blocking an electric current flow is formed from an upper surface of the back electrode layer to an upper surface of the buffer layer in a way that it contacts the electrochromic portion from a side.

8. A method of fabricating a solar cell having an electrochromic portion inserted thereinto, the method comprising:
forming back electrode layers on a substrate so as to be spaced apart from each other at an interval;
disposing a mask on the back electrode layers and depositing a light-transmitting portion in a light-transmitting region on a substrate on which the mask is not formed;
inserting, into the light-transmitting portion, an electrochromic portion including a color adjustment region formed so as to implement a variety of colors according to applied voltage;
forming a buffer layer and a light-absorbing layer, on the back electrode layer and the electrochromic portion;
forming a first pattern portion at one side of the electrochromic portion so as to partially expose the back electrode layer;
forming a front electrode layer on the buffer layer and in the first pattern portion and forming a connection wiring by inserting a transparent conductive material into the inside of the first pattern portion during the formation of the front electrode layer in the first pattern portion; and
forming, in the first pattern portion, a second pattern portion partially exposing the back electrode layer through an opening in the front electrode layer.

9. The method of claim 8, wherein the electrochromic portion changes a color by changing transparency according to voltage applied to the portion between the back electrode layers.

10. The method of claim 8, wherein the electrochromic portion is formed to have the same height as that of the light-absorbing layer.

11. The method of claim 8, wherein the electrochromic portion is formed higher than an upper surface of the back electrode layer and lower than an upper surface of the light-absorbing layer.

12. The method of claim 8, wherein the electrochromic portion has a structure capable of changing a color through an electrochemical oxidation-reduction reaction and includes an electrochromic component and an electrolyte layer.

13. The method of claim 8, wherein the electrochromic portion is formed to partially overlap the back electrode layer.

14. The method of claim 8, wherein after the formation of the first pattern portion, a barrier for blocking an electric current flow is formed from an upper surface of the back electrode layer to an upper surface of the buffer layer in a way that it contacts the electrochromic portion from a side.
